(19) United States
(12) Patent Application Publication
(10) Pub. No.: US 2026/0206480 A1
(43) Pub. Date: Jul. 16, 2026

(54) COMPOSITION FOR FORMING PHOTO-ACTIVE LAYER AND MANUFACTURING METHOD THEREOF

(71) Applicant: KOREA INSTITUTE OF SCIENCE AND TECHNOLOGY, Seoul (KR)

(72) Inventors: Hae Jung SON, Seoul (KR); Eul-Yong SHIN, Seoul (KR); Yoon Hee JANG, Seoul (KR); Hyunjung JIN, Seoul (KR); Kyeongmin KIM, Seoul (KR)

(21) Appl. No.: 19/251,252

(22) Filed: Jun. 26, 2025

(30) Foreign Application Priority Data
Jan. 15, 2025 (KR) 10-2025-0005938

(51) Int. Cl. H10K 85/10; C08J 9/28; H10K 30/30; H10K 30/50

(52) U.S. Cl. CPC H10K 85/151; C08J 9/283; C08J 2201/0502; C08J 2205/042; C08J 2365/00; C08J 2475/06; H10K 30/30; H10K 30/50

(57) ABSTRACT

The present specification relates to a composition for forming a photo-active layer and a preparation method thereof. The composition for forming a photo-active layer according to an embodiment of the present invention provides excellent optoelectronic and mechanical properties, and the preparation method thereof provides an effect in which a nanoporous film can be conveniently prepared without adding a separate process step.

### CROSS REFERENCE TO RELATED APPLICATION

The present application claims priority to Korean Patent Application No. 10-2025-0005938, filed on Jan. 15, 2025, the entire contents of which are incorporated by this reference.

### BACKGROUND OF THE INVENTION

### Field of the Invention

The present specification discloses a composition for forming a photo-active layer and a preparation method thereof.

### Description of Government-Sponsored Research

This invention was carried out with the support of Ministry of Science and ICT under a research project of Unique Project identification number: 2710010689 and Project identification number: 2020M3H4A1A02084910 titled “Development of technology for stretchable organic photovoltaic modules with high stability”, as part of the research project of “Nano Material Technology Development” managed by National Research Foundation of Korea from January 1 to Dec. 31, 2024.

This invention was carried out with the support of Ministry of Science and ICT under a research project of Unique Project identification number: 2710003240 and Project identification number: 00279418 titled “Development of Recyclable Conjugated Polymers and Upcycling Studies for Organic Electronics”, as part of the research project of “Personal Basic Research (Ministry of Science and ICT)” managed by National Research Foundation of Korea from Mar. 1, 2024 to Feb. 28, 2025.

### Description of the Related Art

Optoelectronic devices have attracted considerable attention as power sources for wearable electronic devices. In particular, for wearable optoelectronic devices to be integrated into human joints and electronic skin, the devices need to have excellent mechanical properties, such as the flexibility to accommodate a deformation rate of 30% or more and excellent adaptability to complex curved surfaces. Such stretchable optoelectronic devices may be manufactured by introducing stretchable organic semiconductors into each layer of the device. In this case, it is essential for the optoelectronic device to obtain high electrical performance that a photo-active layer needs to be stretchable. However, it still remains a challenge to fabricate organic semiconductors that simultaneously exhibit excellent electrical properties and high mechanical stretchability. Although the rigid π-conjugated backbones and highly ordered domains of organic molecules are advantageous for charge transport, there is generally a trade-off between the optoelectronic and mechanical properties, as a film is prone to cracking when subjected to mechanical deformation. Although the elasticity of conjugated polymers may be improved through molecular design, such as the introduction of soft building blocks into the polymer backbone, it requires complex organic synthesis and the soft, non-conducting blocks hinder efficient charge carrier transport. Accordingly, there is a need for the dissipation of stress applied through a substrate in order to improve the mechanical properties of organic semiconductors.

### SUMMARY OF THE INVENTION

An object according to one aspect of the present invention is to provide a composition for forming a photo-active layer having excellent optoelectronic and mechanical properties, and a preparation method thereof, which allows a nanoporous film to be conveniently prepared without adding a separate process step.

In one aspect of the present invention, the present invention provides a composition for forming a photo-active layer, including an electron donor material, an electron acceptor material, and a pore-forming agent, wherein the pore-forming agent is a thermoplastic polyurethane.

In another aspect, the present invention provides a photo-active layer including the composition for forming a photo-active layer.

In still another aspect, the present invention provides an organic solar cell including the photo-active layer.

In yet another aspect, the present invention provides a method for preparing the composition for forming a photo-active layer, the method including: preparing a first solution including an electron donor material, an electron acceptor material, and a volatile good solvent; preparing a second solution including a pore-forming agent and a non-volatile non-solvent; and mixing the first solution and the second solution, and then evaporating the volatile good solvent and the non-volatile non-solvent, wherein the pore-forming agent is a thermoplastic polyurethane, and nanopores are formed due to the difference in evaporation rate between the volatile good solvent and the non-volatile non-solvent.

The composition for forming a photo-active layer according to an embodiment of the present invention provides excellent optoelectronic and mechanical properties, and the preparation method thereof provides an effect in which a nanoporous film can be conveniently prepared without adding a separate process step.

### BRIEF DESCRIPTION OF THE DRAWINGS

FIGS. 1A, 1B, 1C, and 1D are atomic force microscopy images measuring the pore structure of a film for a photo-active layer according to an example of the present invention.

FIGS. 2A, 2B, 2C, and 2D are scanning electron microscope images measuring the pore morphology of a film for a photo-active layer according to an example of the present invention.

FIG. 3 is a graph illustrating a current density-voltage (J-V) curve of an organic solar cell according to an example of the present invention.

FIG. 4 is a graph illustrating a space charge limited current (SCLC) curve of an organic solar cell according to an example of the present invention.

FIG. 5 is a graph illustrating a current density-voltage (J-V) curve of an organic solar cell module according to an example of the present invention.

FIG. 6 is a graph illustrating a normalized power conversion efficiency of an organic solar cell module according to an example of the present invention.

FIG. 7 is a graph illustrating a current density-voltage (J-V) curve of an organic solar cell module according to an example of the present invention.

FIGS. 8A and 8B are graphs showing the interfacial adhesion energy evaluation results of a photo-active layer according to an example of the present invention.

FIG. 9 is a graph illustrating a normalized power conversion efficiency of an organic solar cell module according to an example of the present invention.

FIG. 10 is a schematic view illustrating the configuration of an organic solar cell module according to an example of the present invention.

FIG. 11 is a photograph illustrating a film for a photo-active layer according to an example of the present invention.

FIG. 12 is a graph illustrating the average diameter of nanopores formed in a film for a photo-active layer according to an example of the present invention.

FIG. 13 is a photograph illustrating an organic solar cell module according to an example of the present invention.

FIG. 14 is a graph illustrating a current density-voltage (J-V) curve of an organic solar cell according to an example of the present invention.

### DETAILED DESCRIPTION OF THE INVENTION

Hereinafter, preferred examples of the present invention will be described in detail with reference to the accompanying drawings.

The examples of the present invention disclosed herein are exemplified for the purpose of describing the examples of the present invention only, and the examples of the present invention may be carried out in various forms and should not be construed to be limited to the examples described herein. Since the present invention may have various changes and different forms, it should be understood that the Examples are not intended to limit the present invention to specific disclosure forms and they include all the changes, equivalents and replacements included in the spirit and technical scope of the present invention.

In the present specification, when one part “includes” one constituent element, unless otherwise specifically described, this does not mean that another constituent element is excluded, but means that another constituent element may be further included.

The same reference numerals are attached to similar parts throughout the specification. Throughout the specification, when a part such as a layer, a film, a region, and a plate is present “on” or “over” another part, this includes not only a case where the part is present immediately on another part, but also a case where still another part is present therebetween. Throughout the specification, terms such as first and second may be used to describe various components, but the components should not be limited by the terms. The terms are used only to distinguish one component from another.

### Composition for Forming Photo-Active Laver

In one aspect of the present invention, the present invention provides a composition for forming a photo-active layer, including an electron donor material, an electron acceptor material, and a pore-forming agent, wherein the pore-forming agent is a thermoplastic polyurethane.

The present inventors have found that when a thermoplastic polyurethane is used as a pore-forming agent, a nanoporous bulk-heterojunction (np-BHJ) is formed to improve the interfacial adhesion with other layers and efficiently dissipate stress applied to the film, thereby completing the present invention.

In an embodiment, the thermoplastic polyurethane is represented by the following Chemical Formula 1.

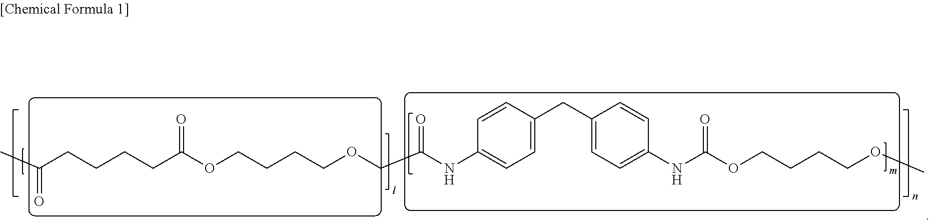

l is an integer from 0 to 10, m is an integer from 0 to 10, and n is an integer from 100 to 500.

In an embodiment, the thermoplastic polyurethane is a block copolymer having a soft segment represented by l and a hard segment represented by n, and its characteristics such as surface energy and solubility parameter may be controlled by manipulating the composition of the segments.

In an embodiment, the ratio of l to n (l:n) in Chemical Formula 1 is 2 to 5:1.

In an embodiment, the pore-forming agent is included at a content of 10 wt % to 30 wt % based on the total weight of the composition.

### Photo-Active Layer and Organic Solar Cell

In another aspect, the present invention provides a photo-active layer including the composition for forming a photo-active layer.

In an embodiment, the photo-active layer is of a nanoporous bulk-heterojunction (np-BHJ) type including nanopores. According to the structure of the photo-active layer, organic solar cells are divided into a bi-layer p-n junction structure in which p-type and n-type semiconductors are composed of separate layers, and a bulk heterojunction (BHJ) type in which p-type and n-type semiconductors are mixed. The bulk heterojunction (BHJ) type solar cells is a solar cell in a form in which an active layer that generates electrons and holes is manufactured by mixing electron donor materials and electron acceptor materials in order to generate the maximum number of electron/hole pairs when irradiated with sunlight.

In an embodiment, nanopores of the photo-active layer have an average diameter of 250 nm to 500 nm and an average depth of 25 nm to 60 nm. More specifically, the average diameter of the nanopores of the photo-active layer may be 250 nm or more, 300 nm or more, 350 nm or more, 379 nm or more; 500 nm or less, 450 nm or less, 400 nm or less, 379 nm or less, but is not limited thereto. More specifically, the average depth of the nanopores of the photo-active layer may be 25 nm or more, 30 nm or more, 35 nm or more, 40 nm or more, 45 nm or more, 50 nm or more, 55 nm or more, 56.3 nm or more; 60 nm or less, 56.3 nm or less, but is not limited thereto.

In still another aspect, the present invention provides an organic solar cell including the photo-active layer. The organic solar cell is not particularly limited as long as it has a typical organic solar cell configuration, and basically includes a substrate, a first electrode (lower electrode), a hole transport layer, a photo-active layer, an electron transport layer, and a second electrode (upper electrode), but it is possible to add components such as a buffer layer according to the application or if necessary.

The organic solar cell according to the present invention may be used as a power source for wearable electronic devices and may be utilized as a sensor with a photodetector.

### Method for Preparing Composition for Forming Photo-Active Laver

In yet another aspect, the present invention provides a method for preparing the composition for forming a photo-active layer, the method including: preparing a first solution including an electron donor material, an electron acceptor material, and a volatile good solvent; preparing a second solution including a pore-forming agent and a non-volatile non-solvent; and mixing the first solution and the second solution, and then evaporating the volatile good solvent and the non-volatile non-solvent, wherein the pore-forming agent is a thermoplastic polyurethane, and nanopores are formed due to the difference in evaporation rate between the volatile good solvent and the non-volatile non-solvent.

The preparation method according to the present invention provides an effect in which a nanoporous film can be conveniently prepared without adding a separate process step. During the evaporation of the solvent, a cast film undergoes phase separation. An organic semiconductor-rich phase forms the bulk-heterojunction (BHJ) matrix of the photo-active film, and an organic semiconductor-deficient phase forms pores. More specifically, the organic semiconductor-rich phase precipitates to form a bulk-heterojunction (BHJ) matrix, and after the non-volatile non-solvent is evaporated, the organic semiconductor-deficient phase forms pores.

Therefore, the pore-forming agent should have high solubility in the non-solvent while at the same time being highly compatible with the organic semiconductor material. Accordingly, the interface between the organic semiconductor-rich and organic semiconductor-deficient phases is effectively stabilized. Pore-forming agents that are highly compatible with organic semiconductors stabilize the organic semiconductor-deficient phase at the interface between the two phases.

In an embodiment, the volatile good solvent is evaporated to form a bulk-heterojunction (BHJ) matrix by phase separation between an organic semiconductor-rich phase and an organic semiconductor-deficient phase, and the non-volatile non-solvent is evaporated to form nanopores.

In an embodiment, the content ratio of the electron donor material to the electron acceptor material (electron donor material:electron acceptor material) in the first solution is 1:1 to 2 by weight.

Hereinafter, the present invention will be described in detail with reference to preferred embodiments such that a person with ordinary skill in the art to which the present invention pertains can easily carry out the present invention. However, the present invention can be implemented in various different forms, and is not limited to the embodiments described herein.

### EXAMPLES

### <Preparation Example 1> Preparation of Film for Photo-Active Layer

A first solution including PM6 (poly[(2,6-(4,8-bis(5-(2-ethylhexyl-3-fluoro)thiophen-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5‘-c’]dithiophene-4,8-dione)]) as an electron donor material, N3 (2,2′-((2Z,2′Z)-((12,13-bis(3-ethylheptyl)-3,9-diundecyl-12,13-dihydro-[1,2,5]thiadiazolo[3,4-e]thieno[2″,3″:4′,5′]thieno[2′,3′:4,5]pyrrolo[3,2-g]thieno[2′,3′:4,5]thieno[3,2-b]indole-2,10-diyl)bis(methaneylylidene))bis(5,6-difluoro-3-oxo-2,3-dihydro-1H-indene-2,1-diylidene))dimalononitrile) as an electron acceptor material, and chloroform (CF) as a volatile good solvent was prepared. PM6 and N3 are represented by the following Chemical Formulae 2 and 3, respectively, and the content ratio of PM6 to N3 (PM6:N3) was 1:1.2.

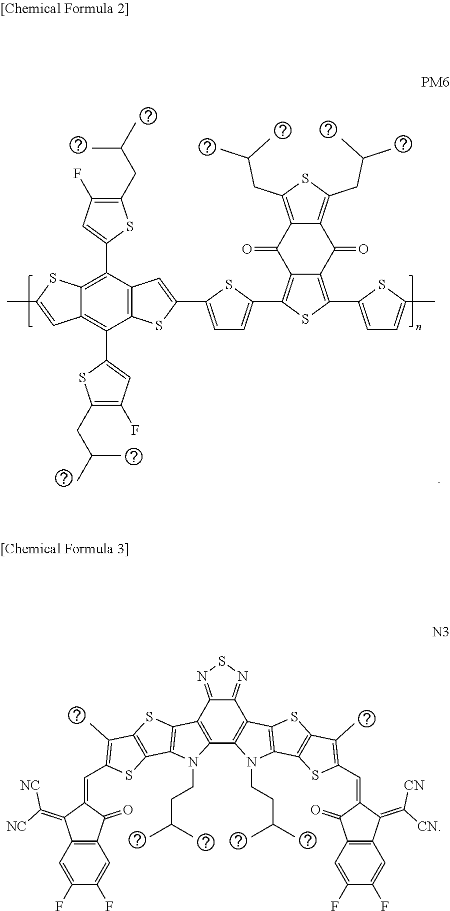

Subsequently, a second solution including a thermoplastic polyurethane (TPU) as a pore-forming agent and N,N-dimethyl formamide (DMF) as a non-volatile non-solvent was prepared. The thermoplastic polyurethane has an interaction parameter (χ) with PM6 and N3 of 1.64 and 0.48, respectively. The thermoplastic polyurethane has a soft segment to hard segment ratio of 8.2.

Subsequently, the first solution and the second solution were mixed to prepare a composition for forming a photo-active layer. The thermoplastic polyurethane was included in an amount of 10 wt %, 20 wt %, 30 wt %, and 40 wt %, respectively, based on the total weight of the composition.

Subsequently, the volatile good solvent and the non-volatile non-solvent were evaporated from the composition to prepare a film for a photo-active layer.

### <Experimental Example 1> Measurement of Pore Structure of Film for Photo-Active Laver

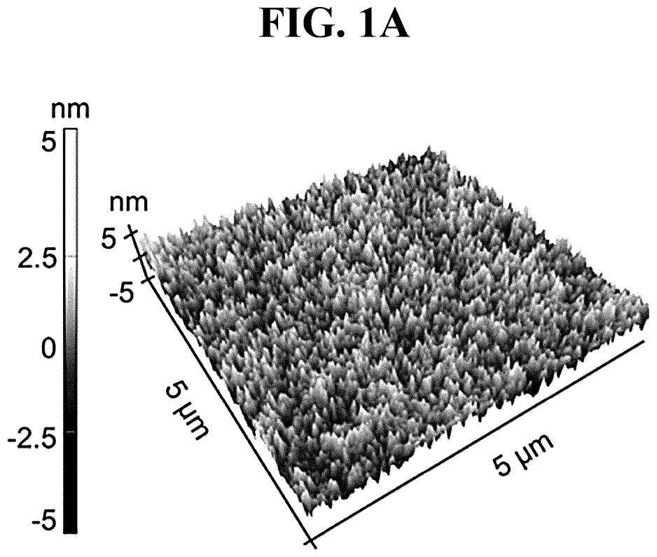

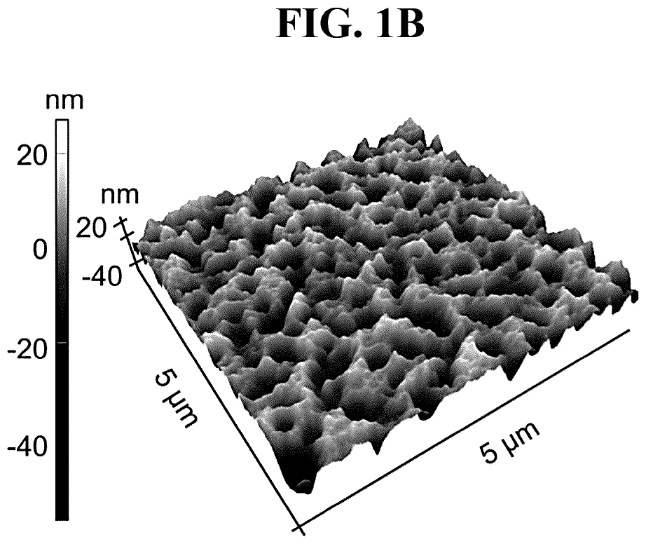

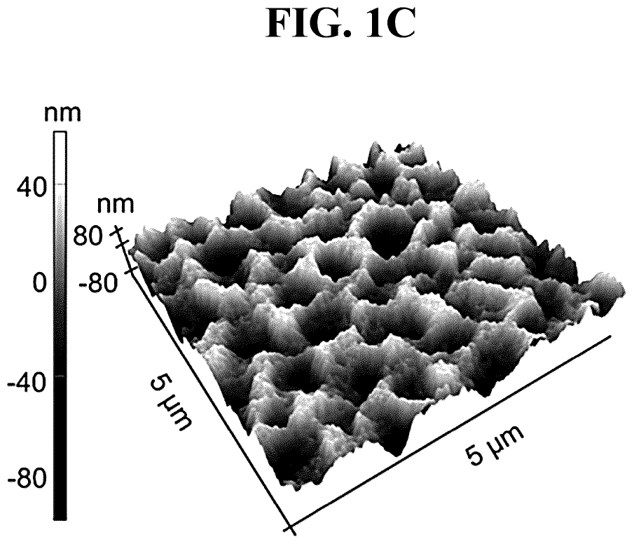

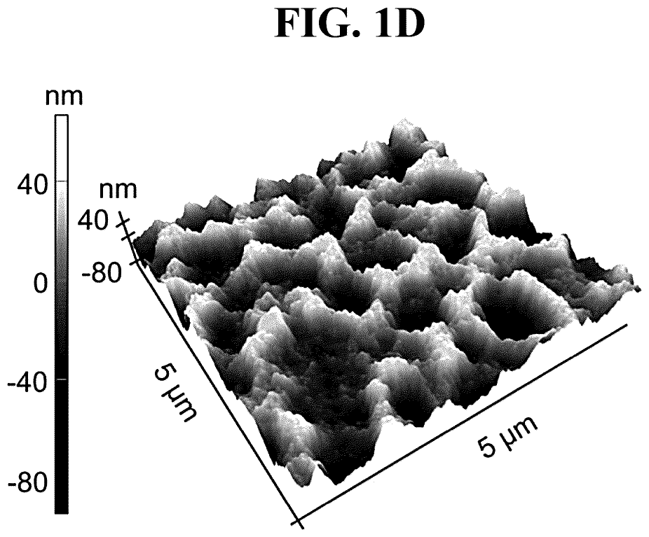

The pore structure of the photo-active layer film prepared in Preparation Example 1 was measured. FIGS. 1A to 1D are atomic force microscopy (AFM) images measuring the pore structure of a film for a photo-active layer according to an example of the present invention (in FIGS. 1A to 1D, the content of thermoplastic polyurethane is 0 wt %, 10 wt %, 20 wt %, and 30 wt %, respectively). From FIGS. 1A to 1D, it can be confirmed that the film for a photo-active layer without thermoplastic polyurethane shows a uniform surface (FIG. 1A), while the film for a photo-active layer with added thermoplastic polyurethane shows nano-level porosity.

### <Experimental Example 2> Measurement of Pore Morphology of Film for Photo-Active Layer

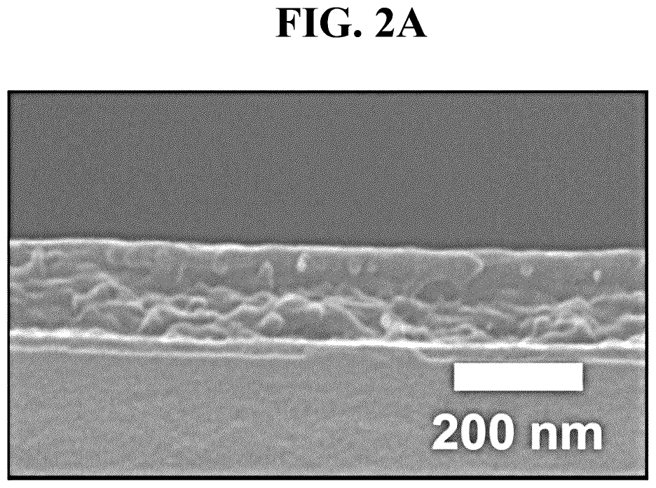

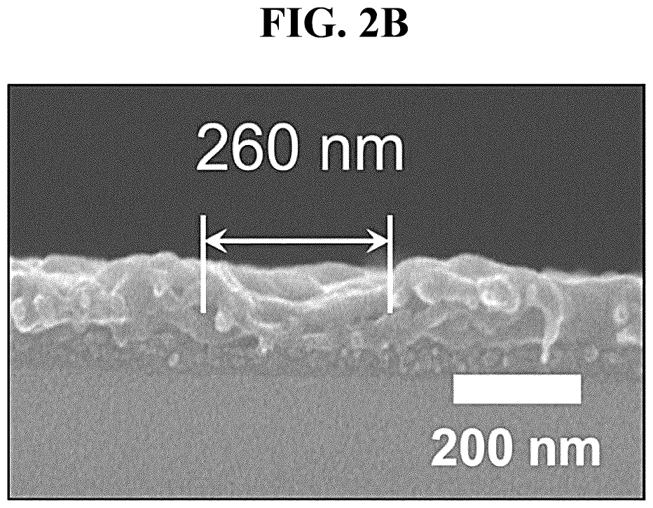

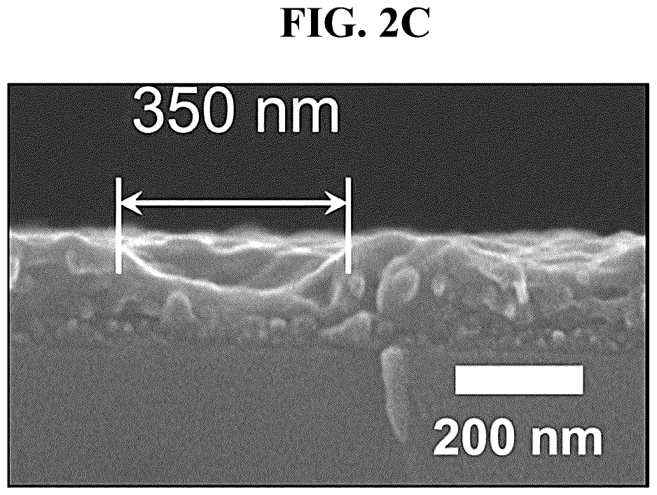

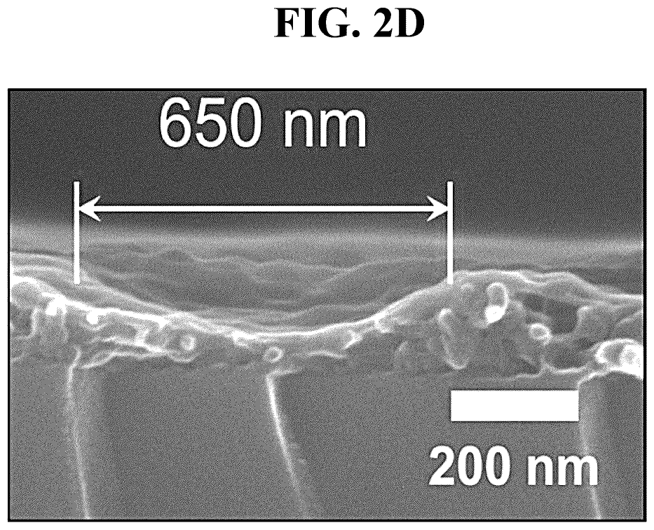

The pore morphology of the photo-active layer film prepared in Preparation Example 1 was measured. FIGS. 2A to 2D are scanning electron microscope (SEM) images measuring the pore morphology of a film for a photo-active layer according to an example of the present invention (in FIGS. 2A to 2D, the content of thermoplastic polyurethane is 0 wt %, 10 wt %, 20 wt %, and 30 wt %, respectively). From FIGS. 2A to 2D, it was found that the pore length varies depending on the content of thermoplastic polyurethane. More specifically, it was found that when the content of thermoplastic polyurethane was 10 wt %, 20 wt %, and 30 wt %, the pore diameter gradually increased at 250.3±12 nm, 379.0±29 nm, and 620±107 nm, respectively, and the pore depth became deeper at 24.57±1.3 nm, 56.3±3.6 nm, and 73.7±3.1 nm, respectively. Further, it can be confirmed that for all the compositions, the films form an interconnected network structure with high uniformity, although the porous structure extends throughout the film.

### <Preparation Example 2> Preparation of Organic Solar Cell

An organic solar cell with a structure having a thermoplastic polyurethane (TPU) stretchable substrate, modified PEDOT:PSS (PH1000) as a bottom electrode, PEDOT:PSS (AI 4083) as a hole transport layer, a film for a photo-active layer according to an embodiment of the present invention as an active layer, N,N′-bis(N-dimethylpropan-1-amine oxide) perylene-3,4,9,10-tetracarboxylic diimide (PDINO) as an electron transport layer, and a eutectic gallium-indium (EGaIn) alloy as a top electrode was prepared.

### <Experimental Example 3> Evaluation of Charge Transfer Efficiency of Organic Solar Cell

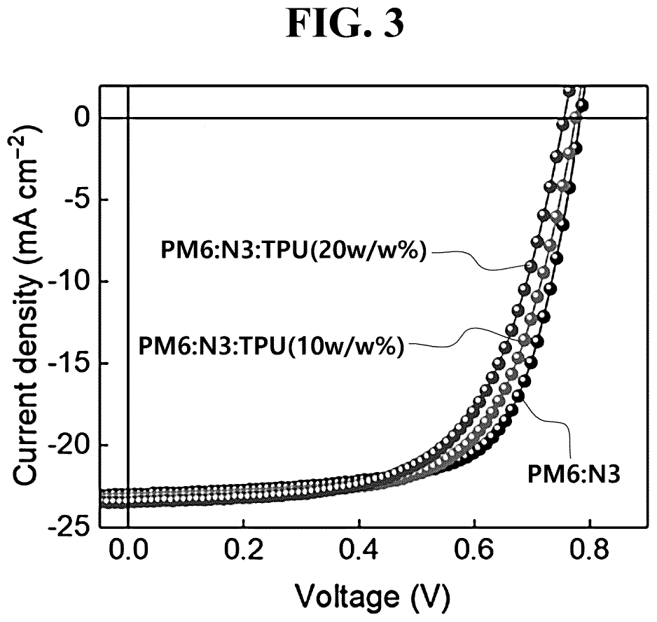

The current density depending on the voltage for the organic solar cell manufactured in Preparation Example 2 was measured to evaluate the power conversion efficiency (PCE). The results are shown in FIG. 3 and Table 1 (average values measured 20 times). FIG. 3 is a graph illustrating a current density-voltage (J-V) curve of an organic solar cell according to an example of the present invention (V_{OC}: open circuit voltage, J_{SC}: short circuit current density, FF: fill factor, and PCE: power conversion efficiency).

TABLE 1

| Photo- | | | | | | |
|---|---|---|---|---|---|---|
| active | TPU | | | J_{SC} (mA | | PCE (max) |
| layer | (wt %) | Process | V_{OC} (V) | cm⁻²) | FF (%) | (%) |
| PM6:N3 | — | Spin coating | 0.78 ± 0.001 | 23.0 ± 0.14 | 67.0 ± 0.32 | 12.1(12.4) ± 0.06 |
| PM6:N3:TPU | 10 | Spin coating | 0.77 ± 0.001 | 23.1 ± 0.09 | 63.7 ± 0.34 | 11.4(12.0) ± 0.09 |
| PM6:N3:TPU | 200 | Spin coating | 0.76 ± 0.001 | 22.9 ± 0.10 | 62.2 ± 0.16 | 10.8(11.0) ± 0.05 |

From FIG. 3 and Table 1, it can be confirmed that a device using a film including thermoplastic polyurethane (10 wt %) had a short circuit current density (J_{SC}) of 23.1 mA cm⁻², a fill factor (FF) of 63.7% and an open circuit voltage (V_{OC}) of 0.77 V, and showed a slightly lower PCE of 12.0% compared to the device using the film without thermoplastic polyurethane (12.4%), and that a device using a film including thermoplastic polyurethane (20 wt %) had a short circuit current density (J_{SC}) of 22.9 mA cm⁻², a fill factor (FF) of 62.2% and an open circuit voltage (V_{OC}) of 0.76 V, and achieved a similar PCE of 11.0%. From this, it can be seen that both holes and electrons are efficiently transferred through well-interconnected channels in the nanoporous bulk-heterojunction (np-BHJ).

### <Experimental Example 4> Evaluation of Charge Mobility of Organic Solar Cell

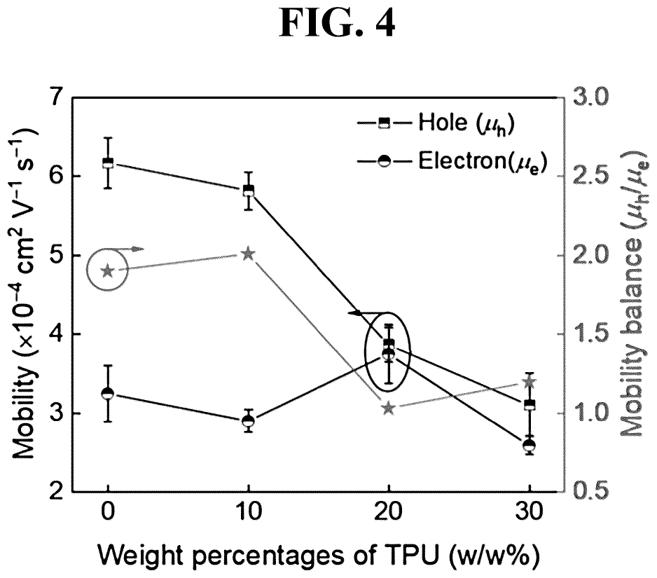

The charge mobility of the organic solar cell manufactured in Preparation Example 2 was evaluated. The results are illustrated in FIG. 4. FIG. 4 is a graph illustrating a space charge limited current (SCLC) curve of an organic solar cell according to an example of the present invention (standard deviation is shown by error bars).

From FIG. 4, the films for a photo-active layer including 0, 10, 20, and 30 wt % thermoplastic polyurethane exhibited hole mobilities of 6.16×10⁻⁴, 5.81×10⁻⁴, 3.86×10⁻⁴, and 3.1×10⁻⁴ cm² V⁻¹ s⁻¹, respectively, which are slightly lower than that of the film without thermoplastic polyurethane (cm² V⁻¹ s⁻¹). The electron mobilities of the films for a photo-active layer were found to be similar. More specifically, the films for a photo-active layer including 0, 10, 20, and 30 wt % thermoplastic polyurethane exhibited electron mobilities of 3.24×10⁻⁴, 2.89×10⁻⁴, 3.74×10⁻⁴, and 2.59×10⁻⁴ cm² V⁻¹ s⁻¹, respectively.

The μₕ/μₑ ratios for films without thermoplastic polyurethane and with 10, 20, and 30 wt % thermoplastic polyurethane were found to be 1.89, 2.00, 1.03, and 1.19, respectively. In particular, when the thermoplastic polyurethane is contained at 20 wt %, it can be confirmed that a relatively well-balanced charge carrier transport is exhibited despite the high porosity. From these observations, it can be seen that the nanoporous bulk-heterojunction (np-BHJ) formed by containing thermoplastic polyurethane forms a network channel for transporting both holes and electrons.

### <Experimental Example 5> Evaluation of Charge Transfer Efficiency of Organic Solar Cell Module

To evaluate the applicability of organic solar cells to large area devices, a module device consisting of individual cells connected in series with a total active area of 0.695 cm² was prepared (V_{OC}: open circuit voltage, J_{SC}: short circuit current density, FF: fill factor, and PCE: power conversion efficiency).

TABLE 2

| Photo- | | | | | | |
|---|---|---|---|---|---|---|
| active | TPU | | | J_{SC} (mA | | PCE (max) |
| layer | (wt %) | Process | V_{OC} (V) | cm⁻²) | FF (%) | (%) |
| PM6:N3 | — | Blade coating | 1.56 ± 0.001 | 10.3 ± 0.09 | 49.7 ± 0.02 | 8.06(8.32) ± 0.14 |
| | | (two lines) | | | | |
| PM6:N3:TPU | 10 | Blade coating | 1.52 ± 0.013 | 10.0 ± 0.02 | 50.9 ± 0.66 | 7.81(8.09) ± 0.10 |
| | | (two lines) | | | | |
| PM6:N3:TPU | 200 | Blade coating | 1.47 ± 0.004 | 9.94 ± 0.07 | 49.4 ± 0.78 | 7.24(7.73) ± 0.10 |
| | | (two lines) | | | | |

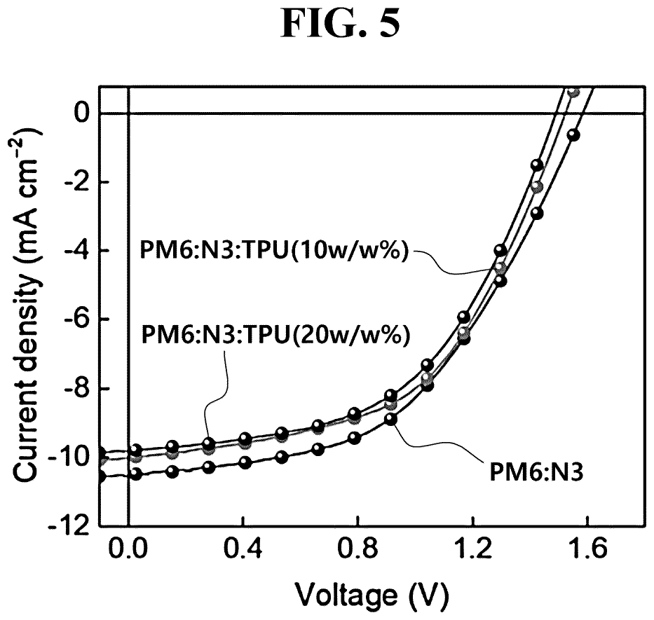

The current density depending on the voltage for the prepared organic solar cell module was measured to evaluate the power conversion efficiency (PCE). The results are shown in FIG. 5 (average values measured 20 times). FIG. 5 is a graph illustrating a current density-voltage (J-V) curve of an organic solar cell module according to an example of the present invention.

From FIG. 5, it can be confirmed that a module using a film including thermoplastic polyurethane (10 wt %) had a short circuit current density (J_{SC}) of 10.0 mA cm⁻², a fill factor (FF) of 50.9% and an open circuit voltage (V_{OC}) of 1.52 V, and showed a similar PCE of 8.09% compared to the module using the film without thermoplastic polyurethane (8.32%), and that a module using a film including thermoplastic polyurethane (20 wt %) had a short circuit current density (J_{SC}) of 9.94 mA cm⁻², a fill factor (FF) of 49.4% and an open circuit voltage (V_{OC}) of 1.47 V, and achieved a similar PCE of 7.73%.

### <Experimental Example 6> Evaluation of Tensile Performance of Organic Solar Cell Module

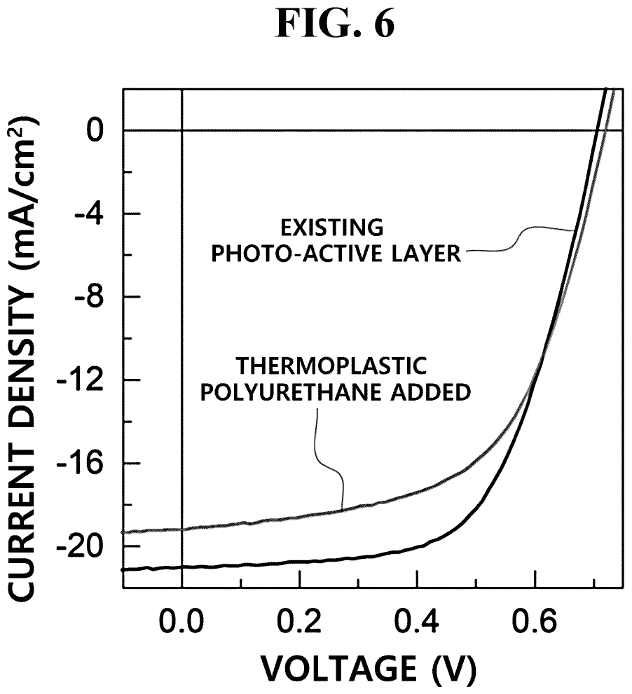

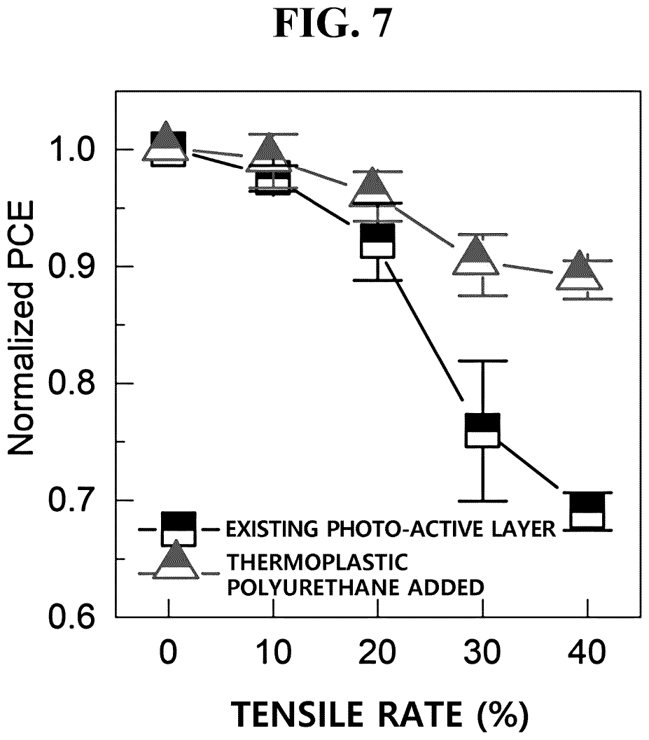

A tensile performance was evaluated for the organic solar cell module. A change in performance was monitored as a function of tensile strain. The results are illustrated in FIGS. 6 and 7. FIG. 6 is a graph illustrating a normalized power conversion efficiency of an organic solar cell module according to an example of the present invention. FIG. 7 is a graph illustrating a current density-voltage (J-V) curve of an organic solar cell module according to an example of the present invention. From FIG. 6, a stretchable organic solar cell manufactured with a photo-active layer with added thermoplastic polyurethane exhibits an efficiency value similar to that of organic solar cells using existing photo-active layers, but has improved characteristics to maintain power conversion efficiency during a tensile test. From FIG. 7, it can be confirmed that the organic solar cell module according to the present invention exhibits the ability to maintain power conversion efficiency during the tensile test. More specifically, as a result of measuring the efficiency while increasing the number of corresponding devices, a photo-active layer in the related art showed a 25% decrease in efficiency at a tensile rate of 30%, while the photo-active layer containing thermoplastic polyurethane showed a decrease of only 10%, indicating that a porous photo-active layer at a nano level also had a significant effect on mechanical stability.

### <Experimental Example 7> Evaluation of Interfacial Adhesion Energy of Photo-Active Laver

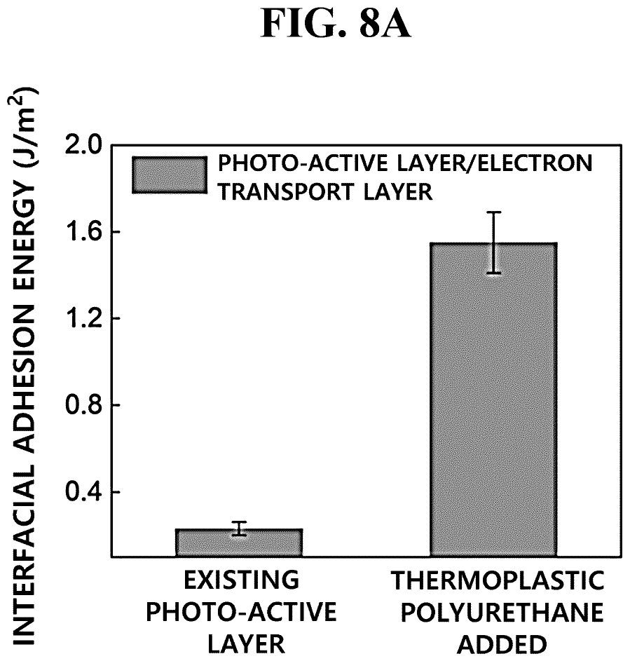

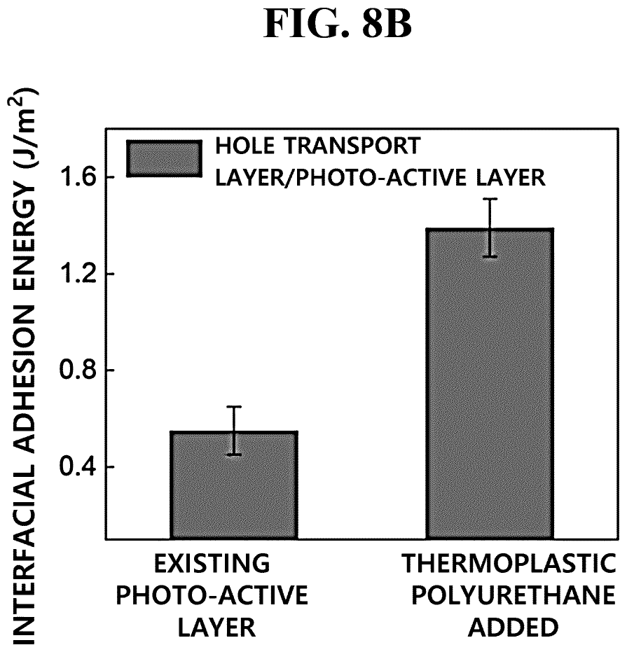

For the organic solar cell module, the interfacial adhesion energy between the photo-active layer and the adjacent layers was evaluated through a double cantilever beam (DCB) experiment. The results are illustrated in FIGS. 8A and 8B. FIGS. 8A and 8B are graphs showing the interfacial adhesion energy evaluation results of a photo-active layer according to an example of the present invention (FIG. 8A: interfacial adhesion energy with electron transport layer, FIG. 8B: interfacial adhesion energy with hole transport layer). From FIG. 8A, it can be confirmed that the film of the present invention exhibited an interfacial adhesion energy with the electron transport layer of 1.55 J m⁻², which is 6.7-fold higher than the film without thermoplastic polyurethane in the related art (0.23 J m⁻²). From FIG. 8B, it can be confirmed that the film of the present invention exhibited an interfacial adhesion energy with the hole transport layer of 1.39 J m⁻², which is 2.5-fold higher than the film without thermoplastic polyurethane in the related art (0.55 J m⁻²).

### <Experimental Example 8> Evaluation of Repeated Tensile Performance of Organic Solar Cell Module

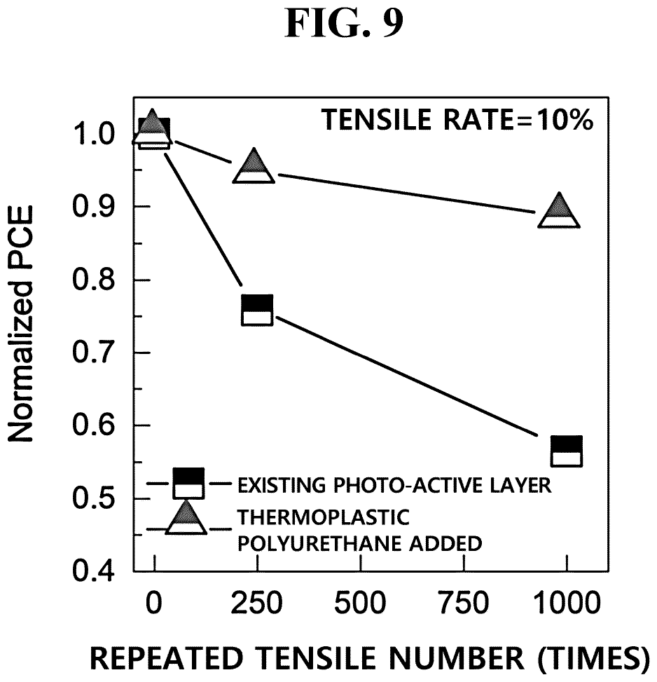

A repeated tensile performance was evaluated for the organic solar cell module. A change in performance was evaluated after 1,000 cycles at a tensile rate of 10%. The results are illustrated in FIG. 9. FIG. 9 is a graph illustrating a normalized power conversion efficiency of an organic solar cell module according to an example of the present invention. From FIG. 9, it can be confirmed that the film of the present invention including 20 wt % thermoplastic polyurethane maintained a power conversion efficiency of 88% compared to before stretching, whereas the film in the related art including no thermoplastic polyurethane showed a very large decrease in power conversion efficiency by 44%.

### <Experimental Example 9> Evaluation of Uniformity of Film for Photo-Active Layer

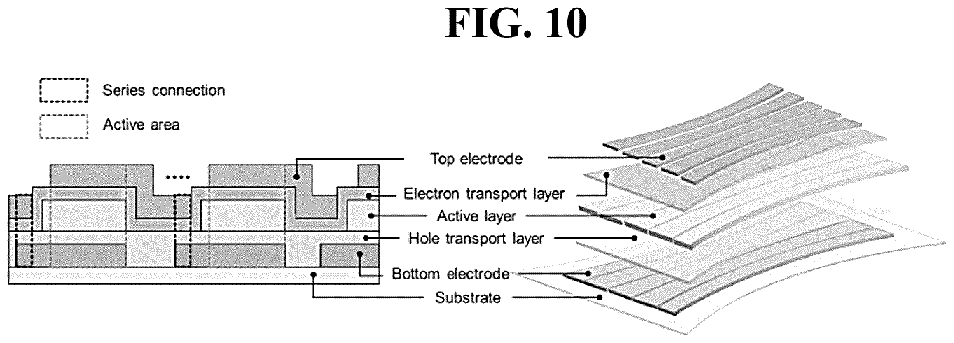

To evaluate the applicability of organic solar cells to large area devices, a module device consisting of four individual cells connected in series was prepared as illustrated in FIG. 10 (V_{OC}: open circuit voltage, J_{SC}: short circuit current density, FF: fill factor, and PCE: power conversion efficiency). FIG. 10 is a schematic view illustrating the configuration of an organic solar cell module according to an example of the present invention.

TABLE 3

| Photo- | | | | | | |
|---|---|---|---|---|---|---|
| active | TPU | | | J_{SC} (mA | | PCE (max) |
| layer | (wt %) | Process | V_{OC} (V) | cm⁻²) | FF (%) | (%) |
| PM6:N3:TPU | 20 | Blade coating | 3.16 ± 0.007 | 4.37 ± 0.02 | 48.8 ± 0.34 | 6.77(7.06) ± 0.05 |
| | | (four lines) | | | | |

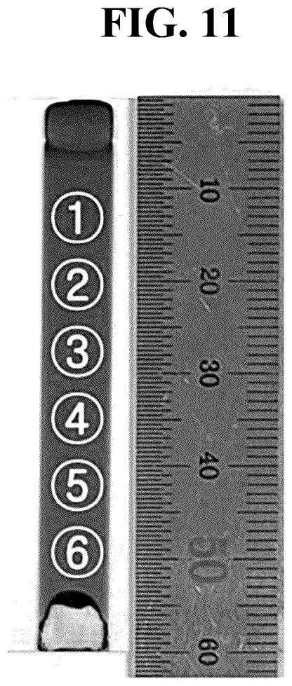

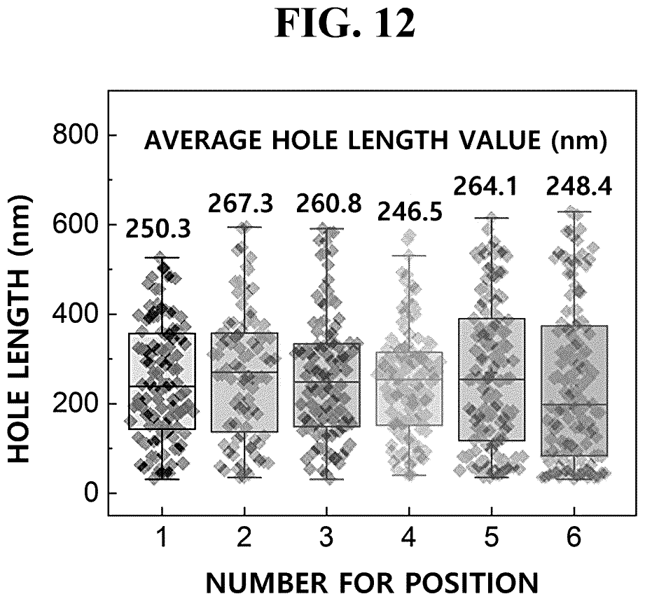

When a photo-active layer including thermoplastic polyurethane was formed into a film with a length of 60 mm through a printing process, it was confirmed whether the film had uniform nanoporosity. A photo-active layer including thermoplastic polyurethane was manufactured and prepared on a substrate with a size of 60 mm×7 mm. FIG. 11 is a photograph illustrating a film for a photo-active layer according to an example of the present invention. The average diameter of the nanopores formed in the film for a photo-active layer was measured from an atomic force microscopy (AFM) image. FIG. 12 is a graph illustrating the average diameter of nanopores formed in a film for a photo-active layer according to an example of the present invention. From FIG. 12, it can be confirmed that the average diameter of the nanopores formed in the film for a photo-active layer is 256.2±3.6 nm. In addition, the difference in average values depending on the position showed a deviation within 5%. From this, it can be seen that a nanoporous polymer thin film can be uniformly formed even over a large area.

### <Experimental Example 10> Evaluation of Charge Transfer Efficiency of Organic Solar Cell Module

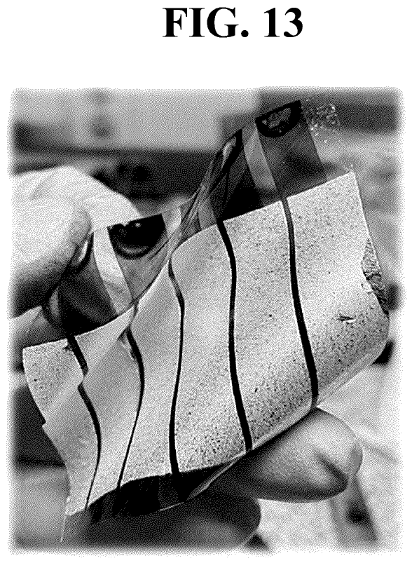

A power conversion efficiency (PCE) was evaluated for an organic solar cell module consisting of four individual cells connected in series. FIG. 13 is a photograph illustrating an organic solar cell module according to an example of the present invention. From FIG. 13, it can be confirmed that a uniform nanoporous thin film can be formed even over a large area, and a large-area stretchable organic solar cell module can be implemented using this.

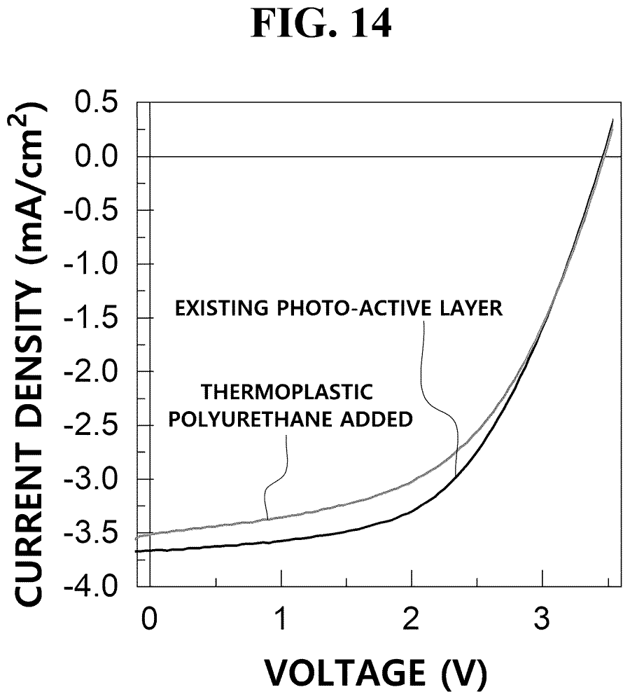

FIG. 14 is a graph illustrating a current density-voltage (J-V) curve of an organic solar cell according to an example of the present invention. From FIG. 14, it can be confirmed that a photo-active layer including no thermoplastic polyurethane exhibits a power conversion efficiency of about 7.25%, and the photo-active layer of the present invention including thermoplastic polyurethane exhibits a power conversion efficiency of 6.7%. From this, it can be confirmed that similar efficiency is maintained even when a nanoporous film is formed by adding thermoplastic polyurethane. This can be used for various applications, such as a power source for sensors attached to the body and a solar cell with any external form.

Although the exemplary embodiments of the present invention have been described above in conjunction with the preferred embodiments mentioned above, various modifications or variations can be made without departing from the spirit and scope of the invention. Therefore, it is intended that the appended claims cover all such modifications and variations as falling within the true spirit and scope of the present invention.

### STATEMENT REGARDING PRIOR DISCLOSURES BY THE INVENTOR OR A JOINT INVENTOR

The inventors of the present application have made the following related disclosure in Eul-Yong Shin et al., “Highly mechanically stable and intrinsically stretchable large-area organic photovoltaics using nanoporous bulk-heterojunction,” Chemical Engineering Journal, Vol. 499, 156116, on Sep. 24, 2024. The related disclosure was made less than one year before the effective filing date (Jan. 15, 2025) of the present application. The inventors of the present application include five authors (Hae Jung Son, Eul-Yong Shin, Yoon Hee Jang, Hyunjung Jin, and Kyeongmin Kim) of the disclosure, and do not include twelve authors (Jaehyeong Park, Dong Jun Kim, So Hyun Park, Kyuyeon Kim, Enoch Go, Jung Sue Kim, Jun Hong Noh, Se-Woong Baek, Boknam Chae, Taek-Soo Kim, Eunji Lee, and Seungjun Chung) of the disclosure. However, these authors did not make contribution to the conception of the invention, and thus are not included in the joint inventors of the present Application. Accordingly, the related disclosure is grace period inventor disclosure, and thus is disqualified from prior art under 35 U.S.C § 102(a)(1) against the present application. See 35 U.S.C § 102(b)(1)(A).

What is claimed is:

1. A composition for forming a photo-active layer, the composition comprising an electron donor material, an electron acceptor material, and a pore-forming agent, wherein the pore-forming agent is a thermoplastic polyurethane.

2. The composition of claim 1, wherein the thermoplastic polyurethane is represented by the following Chemical Formula 1: 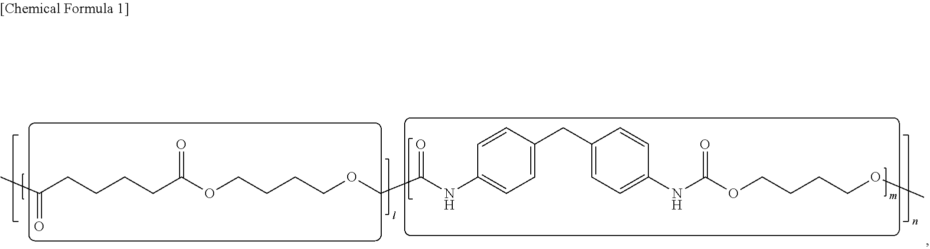
l is an integer from 0 to 10,
m is an integer from 0 to 10, and
n is an integer from 100 to 500.

3. The composition of claim 2, wherein a ratio of l to n (l:n) in Chemical Formula 1 is 2 to 5:1.

4. The composition of claim 1, wherein the pore-forming agent is comprised at a content of 10 wt % to 30 wt % based on a total weight of the composition.

5. A photo-active layer comprising the composition of claim 1.

6. A photo-active layer comprising the composition of claim 2.

7. A photo-active layer comprising the composition of claim 3.

8. A photo-active layer comprising the composition of claim 4.

9. The photo-active layer of claim 5, wherein the photo-active layer is of a nanoporous bulk-heterojunction (np-BHJ) type comprising nanopores.

10. The photo-active layer of claim 5, wherein nanopores of the photo-active layer have an average diameter of 250 nm to 500 nm and an average depth of 25 nm to 60 nm.

11. An organic solar cell comprising the photo-active layer of claim 5.

12. A method for preparing the composition of claim 1, the method comprising:
preparing a first solution comprising an electron donor material, an electron acceptor material, and a volatile good solvent;
preparing a second solution comprising a pore-forming agent and a non-volatile non-solvent; and
mixing the first solution and the second solution, and then evaporating the volatile good solvent and the non-volatile non-solvent,
wherein the pore-forming agent is a thermoplastic polyurethane, and
nanopores are formed due to a difference in evaporation rate between the volatile good solvent and the non-volatile non-solvent.

13. The method of claim 12, wherein the volatile good solvent is evaporated to form a bulk-heterojunction (BHJ) matrix by phase separation between an organic semiconductor-rich phase and an organic semiconductor-deficient phase, and
the non-volatile non-solvent is evaporated to form nanopores.

14. The method of claim 12, wherein a content ratio of the electron donor material to the electron acceptor material (electron donor material:electron acceptor material) in the first solution is 1:1 to 2 by weight.
